(19) United States
(12) Patent Application Publication
(10) Pub. No.: US 2020/0308450 A1
(43) Pub. Date: Oct. 1, 2020

(54) POLISHING COMPOSITION

(71) Applicant: FUJIMI INCORPORATED, Kiyosu-shi (JP)

(72) Inventors: Toshio SHINODA, Kiyosu-shi (JP); Daiki ITO, Kiyosu-shi (JP)

(73) Assignee: FUJIMI INCORPORATED, Kiyosu-shi (JP)

(21) Appl. No.: 16/823,484

(22) Filed: Mar. 19, 2020

(30) Foreign Application Priority Data
Mar. 29, 2019 (JP) 2019-066859

(51) Int. Cl. C09G 1/02; C09G 1/18

(52) U.S. Cl. CPC C09G 1/02; H01L 21/3212; C09G 1/18

(57) ABSTRACT

The object of the present invention is to provide a novel polishing composition capable of polishing two or more kinds of objects to be polished at a similar speed and at a high speed.

A polishing composition used for polishing an object to be polished, the polishing composition including: abrasive grains; an organic compound; and a liquid carrier, in which the number of silanol groups per unit surface area of the abrasive grains is more than 0/nm² and equal to or less than 2.5/nm², and the organic compound has a phosphonic acid group or a salt group thereof.

### CROSS-REFERENCE TO RELATED APPLICATION

### Background

### 1. Technical Field

The present invention relates to a polishing composition.

### 2. Description of Related Arts

In recent years, due to multilayer wiring on a surface of a semiconductor substrate, a so-called chemical mechanical polishing (CMP) technique for physically polishing and planarizing a semiconductor substrate has been used, in producing a device. CMP is a method of using a polishing composition (slurry) containing abrasive grains such as silica, alumina, and ceria, anticorrosive agents, surfactants, and the like to planarize a surface of an object to be polished (polished object) such as a semiconductor substrate, and specifically, CMP has been used in processes such as shallow trench isolation (STI), planarization of interlayer insulating film (ILD film), tungsten plug formation, and multilayer wiring composed of copper and a low dielectric constant film.

In recent years, there is a demand for controlling a so-called polishing selection ratio, so as to improve the polishing speed of some objects to be polished and suppress the polishing speed of some objects to be polished, in two or more kinds of objects to be polished.

For example, JP 2016-524004 A discloses a technique for selectively polishing silicon oxide with respect to silicon nitride in an object to be polished having silicon nitride and silicon oxide.

### SUMMARY

The present inventors have found that there is a problem that it is desired that two or more kinds of objects to be polished are polished at a similar speed and at a high speed, in the process of intensively studying the control of the polishing selection ratio. Therefore, an object of the present invention is to provide a novel polishing composition capable of polishing two or more kinds of objects to be polished at a similar speed and at a high speed.

The present inventors have intensively studied to solve the above problem. As a result, the above problem is solved by a polishing composition used for polishing an object to be polished, including abrasive grains, an organic compound, and a liquid carrier, in which the number of silanol groups per unit surface area of the abrasive grains is more than 0/nm² and equal to or less than 2.5/nm², and the organic compound has a phosphonic acid group or a salt group thereof.

The present invention can provide a novel polishing composition capable of polishing two or more kinds of objects to be polished at a similar speed (preferably at the same speed) and at a high speed.

### DETAILED DESCRIPTION

Hereinafter, the present invention will be described. The present invention is not limited to the following embodiment. Unless otherwise stated, operation and measurement of physical properties or the like are performed under the conditions of room temperature (20 to 25° C.)/a relative humidity of 40 to 50% RH.

The present invention relates to a polishing composition used for polishing an object to be polished, including abrasive grains, an organic compound, and a liquid carrier, in which the number of silanol groups per unit surface area of the abrasive grains is more than 0/nm² and equal to or less than 2.5/nm², and the organic compound has a phosphonic acid group or a salt group thereof. With this configuration, two or more kinds of objects to be polished can be polished at a similar speed (preferably at the same speed) and at a high speed. The two or more kinds of objects to be polished may be two, three, or more kinds thereof. The two or more kinds of objects to be polished may be at least two or more kinds selected from the group consisting of silicon oxide (SiO₂), silicon nitride (SiN), and polysilicon, and the three or more kinds of objects to be polished may include silicon oxide (SiO₂), silicon nitride (SiN), and polysilicon, as described below.

### [Object to be Polished]

According to an embodiment of the present invention, the object to be polished includes at least one of silicon oxide (SiO₂) and silicon nitride (SiN). According to an embodiment of the present invention, the object to be polished includes silicon oxide (SiO₂) and silicon nitride (SiN). By applying the polishing composition of the embodiment of the present invention to the object to be polished as such, the object to be polished can be polished at a similar speed (preferably at the same speed) and at a high speed. In an embodiment of the present invention, as silicon oxide (SiO₂), silicon oxide (SiO₂) derived from tetraethyl orthosilicate (TEOS) is suitable. According to an embodiment of the present invention, the object to be polished further includes polysilicon. According to the polishing composition of the embodiment of the present invention, the object to be polished further including polysilicon can be polished at a similar speed (preferably at the same speed) and at a high speed. According to an embodiment of the present invention, the use of the polishing composition is not limited, but it is preferred to use the polishing composition in a semiconductor substrate.

### [Abrasive Grain]

In an embodiment of the present invention, the polishing composition includes abrasive grains, and the surface of the abrasive grain is cationically modified. According to the embodiment, two or more kinds of objects to be polished can be polished at a similar speed (preferably at the same speed) and at a higher speed.

In an embodiment of the present invention, the modification is performed by a chemical bond. According to the embodiment, two or more kinds of objects to be polished can be polished at a similar speed (preferably at the same speed) and at a higher speed.

In an embodiment of the present invention, specific examples of the abrasive grains include particles made of metal oxides such as silica. The abrasive grains may be used alone or in combination of two or more. Further, as the abrasive grains, a commercially available product may be used or a synthesized product may be used. Among these abrasive grains, silica is preferred, fumed silica and colloidal silica are more preferred, and colloidal silica is particularly preferred. Examples of the method of producing colloidal silica include a sodium silicate method and a sol-gel method, and colloidal silica produced by any production method can be suitably used as the abrasive grains of the present invention. However, colloidal silica produced by a sol-gel method which allows production with a high purity is preferred.

In an embodiment of the present invention, the surface of the abrasive grain is cationically modified. In an embodiment of the present invention, examples of the colloidal silica of which the surface is cationically modified preferably include colloidal silica having an amino group or a quaternary ammonium salt group immobilized on the surface. Examples of the method of producing colloidal silica having a cationic group include a method of immobilizing a silane coupling agent having an amino group such as aminoethyl trimethoxysilane, aminopropyl trimethoxysilane, aminoethyl triethoxysilane, aminopropyl triethoxysilane, aminopropyldimethyl ethoxysilane, aminopropylmethyl diethoxysilane, and aminobutyl triethoxysilane, or a silane coupling agent having a quaternary ammonium group such as N-trimethoxysilylpropyl-N,N,N-trimethylammonium on a surface of the abrasive grain, as described in JP 2005-162533 A. Then, colloidal silica having an amino group or a quaternary ammonium group immobilized on the surface can be obtained. In an embodiment of the present invention, the abrasive grains are formed by immobilizing a silane coupling agent having an amino group or a silane coupling agent having a quaternary ammonium group on the surface of the abrasive grain.

In an embodiment of the present invention, the number of silanol groups per unit surface area of the abrasive grains (the number of silanol groups) is more than 0/nm² and equal to or less than 2.5/nm². When the number of silanol groups is more than 2.5/nm², the desired effect of the present invention cannot be achieved. In an embodiment of the present invention, the number of silanol groups is 2.4/nm² or less, less than 2.4/nm², 2.3/nm² or less, 2.2/nm² or less, 2.1/nm² or less, 2.0/nm² or less, 1.9/nm² or less, or 1.8/nm² or less. According to the embodiment, two or more kinds of objects to be polished can be polished at a similar speed (preferably at the same speed) and at a higher speed.

In an embodiment of the present invention, the number of silanol groups is 0.2/nm² or more, 0.4/nm² or more, 0.6/nm² or more, 0.8/nm² or more, 1.0/nm² or more, 1.2/nm² or more, 1.4/nm² or more, 1.5/nm² or more, 1.6/nm² or more, or 1.7/nm² or more. When there is no silanol group, the desired effect of the present invention cannot be achieved. Further, when the number of silanol groups is present at such a lower limit, the dispersibility of the abrasive grains is improved, and two or more kinds of objects to be polished can be polished at a similar speed (preferably at the same speed) and at a higher speed.

In an embodiment of the present invention, in order to reduce the number of silanol groups per unit surface area of the abrasive grains to 2.5/nm² or less, control can be done by selecting the method of producing abrasive grains or the like, and for example, it is preferred to perform heat treatment such as baking. In an embodiment of the present invention, the baking treatment is, for example, to hold abrasive grains (for example, silica) in an environment of 120 to 200° C. for 30 minutes or more. By performing the heat treatment, the number of silanol groups on the surface of the abrasive grains can be a desired numerical value such as 2.5/nm² or less. Unless such a special treatment is performed, the number of silanol groups on the surface of the abrasive grains does not fall into 2.5/nm² or less.

In an embodiment of the present invention, an average primary particle size of the abrasive grains is preferably 10 nm or more, more preferably 15 nm or more, still more preferably 20 nm or more, still more preferably 25 nm or more, still more preferably 30 nm or more, and even more preferably 35 nm or more, or may be 40 nm or more, 45 nm or more, or 50 nm or more. In the polishing composition of the embodiment of the present invention, the average primary particle size of the abrasive grains is preferably 60 nm or less, more preferably 55 nm or less, and still more preferably 53 nm or less, or may be 50 nm or less, or 40 nm or less. When the average primary particle size of the abrasive grains is adjusted to be large, the polishing speed of the object to be polished including silicon oxide tends to be improved, and when the average primary particle size of the abrasive grains is adjusted to be small, the polishing speed of the object to be polished including silicon nitride tends to be improved. Therefore, from the viewpoint of polishing two or more kinds of objects to be polished at a similar speed (preferably at the same speed), it is preferred that the average primary particle size of the abrasive grains is 25 to 53 nm. As the average primary particle size in the present invention, a value measured by the method described in the examples may be adopted.

The average secondary particle size of the abrasive grains is preferably 40 nm or more, more preferably 45 nm or more, still more preferably 50 nm or more, still more preferably 55 nm or more, still more preferably 60 nm or more, still more preferably 65 nm or more, and even more preferably 70 nm or more, or may be 75 nm or more, 80 nm or more, 90 nm or more, 95 nm or more, or 100 nm or more. In an embodiment of the present invention, the average secondary particle size of the abrasive grains is preferably 140 nm or less, and more preferably 120 nm or less, or may be 115 nm or less, 110 nm or less, 105 nm or less, 100 nm or less, 90 nm or less, 80 nm or less, or 75 nm or less. When the average secondary particle size of the abrasive grains is adjusted to be large, the polishing speed of the object to be polished including silicon oxide tends to be improved, and when the average secondary particle size of the abrasive grains is adjusted to be small, the polishing speed of the object to be polished including silicon nitride tends to be improved. Therefore, from the viewpoint of polishing two or more kinds of objects to be polished at a similar speed (preferably at the same speed) and at a high speed, it is preferred that the average secondary particle size of the abrasive grains is 55 to 120 nm. As the average secondary particle size in the present invention, a value measured by the method described in the examples may be adopted.

In an embodiment of the present invention, a lower limit of an average degree of association (average secondary particle size/average primary particle size) of the abrasive grains in the polishing composition is preferably 1.3 or more, more preferably 1.4 or more, still more preferably 1.5 or more, still more preferably 1.6 or more, still more preferably 1.7 or more, still more preferably 1.8 or more, still more preferably 1.9 or more, and even more preferably 2.0 or more, or may be more than 2.0, 2.1 or more, and 2.2 or more. Two or more kinds of objects to be polished can be polished at a similar speed (preferably at the same speed) and at a higher speed. In an embodiment of the present invention, an upper limit of the average degree of association of the abrasive grains in the polishing composition is preferably 4.0 or less, more preferably 3.5 or less, still more preferably 3.0 or less, still more preferably 2.5 or less, and even more preferably 2.4 or less, or may be less than 2.3, 2.2 or less, or 2.1 or less. Two or more kinds of objects to be polished can be polished at a similar speed (preferably at the same speed) and at a higher speed.

In an embodiment of the present invention, the content of the abrasive grains in the polishing composition is preferably 0.01% by mass or more, more preferably 0.05% by mass or more, still more preferably 0.1% by mass or more, still more preferably 0.2% by mass or more, still more preferably 0.3% by mass or more, still more preferably 0.4% by mass or more, and even more preferably 0.5% by mass or more, or may be more than 0.5% by mass, 0.6% by mass or more, 0.7% by mass or more, 0.9% by mass or more, 1.1% by mass or more, or 1.3% by mass or more. Within the lower limit, there is an effect that the polishing speed can be improved. In an embodiment of the present invention, the content of the abrasive grains in the polishing composition is preferably 10% by mass or less, more preferably 8% by mass or less, still more preferably 6% by mass or less, still more preferably 4% by mass or less, even more preferably 2% by mass or less, and even more preferably 1.5% by mass or less, or may be less than 1.5% by mass, less than 1.2% by mass, 1.0% by mass or less, 0.8% by mass or less, or 0.6% by mass or less. Within the upper limit, two or more kinds of objects to be polished can be polished at a similar speed (preferably at the same speed) and at a higher speed.

In particular, when an object to be polished including silicon oxide and silicon nitride is polished, the polishing speed of silicon oxide tends to depend on the content of the abrasive grains (abrasive grain concentration) in the polishing composition rather than the polishing speed of silicon nitride. Therefore, in an embodiment of the present invention, the content of the abrasive grains in the polishing composition is adjusted to preferably 0.1 to 2% by mass, more preferably 0.2 to 1.9% by mass, still more preferably 0.3 to 1.8% by mass, and even more preferably 0.4 to 1.7% by mass. When the content is adjusted to the range, the polishing speed of the object to be polished can be improved as well without excessively increasing the polishing speed of any one object to be polished and excessively decreasing the polishing speed of any one object to be polished. Incidentally, it should be noted that all combinations of the lower limit and upper limit values disclosed in the present specification are disclosed.

### [Organic Compounds]

In an embodiment of the present invention, the polishing composition includes an organic compound, and the organic compound has a phosphonic acid group or a salt group thereof. When the organic compound having a phosphonic acid group or a salt group thereof is not present in the polishing composition, the desired effect of the present invention cannot be achieved. In the present specification, the organic compound having a phosphonic acid group or a salt group thereof is an organic compound having one or more phosphonic acid groups or salt group(s) thereof. Even when the organic compound has an alkyl group substituted with a phosphonic acid group or a salt group thereof, the organic compound clearly has a phosphonic acid group or a salt group thereof, and thus, it should be noted that it falls under the category of the organic compound of the present invention.

In an embodiment of the present invention, the organic compound has, for example, 1 or more, 2 or more, 3 or more, 4 or more, 5 or more, 6 or more, 7 or more, or 8 or more carbon atoms in one molecule. In an embodiment of the present invention, the organic compound has 30 or less, 20 or less, 15 or less, 13 or less, 12 or less, or 11 or less carbon atoms in one molecule.

In an embodiment of the present invention, the organic compound has a nitrogen atom. When the organic compound has a nitrogen atom in addition to the phosphonic acid group or the salt group thereof, the desired effect of the present invention can be efficiently achieved. In an embodiment of the present invention, the organic compound has an unsubstituted alkyl group having 1 to 5 carbon atoms (preferably an unsubstituted alkyl group having 1 to 4 carbon atoms, more preferably an unsubstituted alkyl group having 1 to carbon atoms). When the organic compound has an unsubstituted alkyl group having 1 to 5 carbon atoms in addition to the phosphonic acid group or the salt group thereof, the desired effect of the present invention can be efficiently achieved. In an embodiment of the present invention, the organic compound has a hydroxyl group. When the organic compound has a hydroxyl group in addition to the phosphonic acid group or the salt group thereof, the desired effect of the present invention can be efficiently achieved. In an embodiment of the present invention, the organic compound has 1 to 5 nitrogen atoms in one molecule. In an embodiment of the present invention, the organic compound has 1 to 4 nitrogen atoms in one molecule. In an embodiment of the present invention, the organic compound has 1 to 3 nitrogen atoms in one molecule. In an embodiment of the present invention, the organic compound has 1 to 7, 2 to 6, or 2 to 5 phosphonic acid groups or salt groups thereof in one molecule (an alkyl group substituted with a phosphonic acid group or a salt group thereof). In an embodiment of the present invention, the organic compound has at least one of an unsubstituted alkyl group having 1 to 5 carbon atoms and a hydroxyl group (other than the phosphonic acid group or the salt group thereof) in one molecule.

In an embodiment of the present invention, the organic compound is a compound represented by N(R¹) (R²) (R³) or a salt thereof, a compound represented by C(R¹) (R²) (R³) (R⁴) or a salt thereof, or a compound represented by the following Formula (1) or a salt thereof.

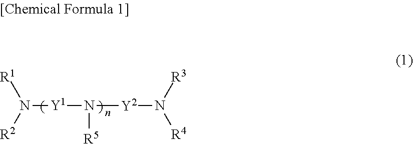

Y¹ and Y² each independently represent a linear or branched alkylene group having 1 to 5 carbon atoms, n is an integer of 0 to 4, and R¹ to R⁵ each independently represent a hydrogen atom, a hydroxyl group, a phosphonic acid group or a salt group thereof, or a substituted or unsubstituted linear or branched alkyl group having 1 to 5 carbon atoms, in which one or more of R¹ to R⁵ are a phosphonic acid group or a salt group thereof or an alkyl group substituted with a phosphonic acid group or a salt group thereof. Here, since R⁴ and R⁵ are not present in N(R¹) (R²) (R³), it goes without saying that “one or more of R¹ to R⁵ are a phosphonic acid group or a salt group thereof or an alkyl group substituted with a phosphonic acid group or a salt group thereof” is replaced with “one or more of R¹ to R³ are a phosphonic acid group or a salt group thereof or an alkyl group substituted with a phosphonic acid group or a salt group thereof”. Likewise, since R⁵ is not present in C(R¹) (R²) (R³) (R⁴), it goes without saying that “one or more of R¹ to R⁵ are a phosphonic acid group or a salt group thereof or an alkyl group substituted with a phosphonic acid group or a salt group thereof” is replaced with one or more of R¹ to R⁴ are a phosphonic acid group or a salt group thereof or an alkyl group substituted with a phosphonic acid group or a salt group thereof”.

In an embodiment of the present invention, as Y¹ and Y², the linear or branched alkylene group having 1 to 5 carbon atoms is not particularly limited, and includes linear or branched alkylene groups such as a methylene group, an ethylene group, a trimethylene group, a tetramethylene group, a propylene group. Among these, a linear or branched alkylene group having 1 to 4 carbon atoms is preferred, and a linear or branched alkylene group having 1 to 3 carbon atoms is more preferred. Further, an alkylene group having 1 or 2 carbon atoms, that is, a methylene group and an ethylene group are more preferred, and an ethylene group is particularly preferred. According to the embodiment, two or more kinds of objects to be polished can be polished at a similar speed (preferably at the same speed) and at a higher speed.

In the above Formula (1), n represents the number of (—Y¹—N(R⁵)—) and is an integer of 0 or more and 4 or less. n is preferably an integer of 0 or more and 2 or less, particularly preferably 0 or 1. According to the embodiment, two or more kinds of objects to be polished can be polished at a similar speed (preferably at the same speed) and at a higher speed. When n is 2 or more, n (—Y¹—N(R⁵)—) may be the same or different.

As R¹ to R⁵, the substituted or unsubstituted linear or branched alkyl group having 1 to 5 carbon atoms is not particularly limited, and includes alkyl groups such as a methyl group, an ethyl group, a propyl group, an isopropyl group, a butyl group, an isobutyl group, a sec-butyl group, and a tert-butyl group. Among these, a substituted or unsubstituted linear or branched alkyl group having 1 to 4 carbon atoms is preferred, and a substituted or unsubstituted linear or branched alkyl group having 1 to 3 carbon atoms is more preferred. Furthermore, a methyl group and an ethyl group are more preferred, and a methyl group is particularly preferred. According to the embodiment, two or more kinds of objects to be polished can be polished at a similar speed and at a higher speed.

Here, “substituted or unsubstituted” for an alkyl group means that one or more hydrogen atoms of the alkyl group may be replaced with other substituents or may not be replaced. Here, the substituent which can be substituted is not particularly limited. Examples of the substituent include a fluorine atom (F); a chlorine atom (Cl); a bromine atom (Br); an iodine atom (I); a phosphoric acid group (—PO₃H₂); a phosphoric acid group (—OPO₃H₂); a thiol group (—SH); a cyano group (—CN); a nitro group (—NO₂); a hydroxy group (—OH); a linear or branched alkoxy group having 1 to 10 carbon atoms (for example, a methoxy group, an ethoxy group, a propoxy group, an isopropoxy group, a butoxy group, a pentyloxy group, a hexyloxy group, a 2-ethylhexyloxy group, an octyloxy group, a dodecyloxy group, and the like); an aryl group having 6 to 30 carbon atoms (for example, a phenyl group, a biphenyl group, a 1-naphthyl group, and a 2-naphthyl group); a cycloalkyl group having 3 to 20 carbon atoms (for example, a cyclopropyl group, a cyclobutyl group, a cyclopentyl group, a cyclohexyl group, and a cycloheptyl group); and the like.

In an embodiment of the present invention, in N(R¹) (R²) (R³), one or more of R¹ to R³ are a phosphonic acid group or a salt group thereof, or an alkyl group substituted with a phosphonic acid group or a salt group thereof. The above description can be similarly applied to the description of R¹ to R³, of course.

In an embodiment of the present invention, in C(R¹) (R²) (R³) (R⁴), one or more of R¹ to R⁴ are a phosphonic acid group or a salt group thereof, or an alkyl group substituted with a phosphonic acid group or a salt group thereof. The above description can be similarly applied to the description of R¹ to R⁴, of course.

In an embodiment of the present invention, in the above Formula (1), one or more of R¹ to R⁵ are a phosphonic acid group or a salt group thereof, or an alkyl group substituted with a phosphonic acid group or a salt group thereof.

Here, the “alkyl group substituted with a phosphonic acid group” is a linear or branched alkyl group having 1 to 5 carbon atoms substituted with one or more phosphonic acid groups, and examples thereof include a (mono)phosphonomethyl group, a (mono)phosphonoethyl group, a (mono)phosphono-n-propyl group, a (mono)phosphonoisopropyl group, a (mono) phosphono-n-butyl group, a (mono)phosphonoisobutyl group, a (mono)phosphono-s-butyl group, a (mono)phosphono-t-butyl group, a diphosphonomethyl group, a diphosphonoethyl group, a diphosphono-n-propyl group, a diphosphonoisopropyl group, a diphosphono-n-butyl group, a diphosphonoisobutyl group, a diphosphono-s-butyl group, a diphosphono-t-butyl group, and the like. Among these, a linear or branched alkyl group having 1 to 4 carbon atoms substituted with one phosphonic acid group is preferred, and a linear or branched alkyl group having 1 to 3 carbon atoms substituted with one phosphonic acid group is more preferred. According to the embodiment, two or more kinds of objects to be polished can be polished at a similar speed (preferably at the same speed) and at a higher speed. Furthermore, a (mono)phosphonomethyl group and a (mono)phosphonoethyl group are more preferred, and a (mono)phosphonomethyl group is particularly preferred. According to the embodiment, two or more kinds of objects to be polished can be polished at a similar speed (preferably at the same speed) and at a higher speed.

In an embodiment of the present invention, the organic compound has two or more phosphonic acid groups or salt groups thereof or two or more alkyl groups substituted with a phosphonic acid groups or a salt group thereof. Thus, when the organic compound has a structure derived from two or more phosphonic acid groups, the desired effect of the present invention is efficiently achieved.

In an embodiment of the present invention, it is preferred that two or more of N(R¹) (R²) (R³) are a phosphonic acid group or a salt group thereof, or an alkyl group substituted with a phosphonic acid group or a salt group thereof, and it is more preferred that all of three of N(R¹) (R²) (R³) are a phosphonic acid group or a salt group thereof, or an alkyl group substituted with a phosphonic acid group or a salt group thereof. According to the embodiment, two or more kinds of objects to be polished can be polished at a similar speed (preferably at the same speed) and at a higher speed.

In an embodiment of the present invention, it is preferred that two or more in C(R¹) (R²) (R³) (R⁴) are a phosphonic acid group or a salt group thereof, or an alkyl group substituted with a phosphonic acid group or a salt group thereof. According to the embodiment, two or more kinds of objects to be polished can be polished at a similar speed (preferably at the same speed) and at a higher speed. In an embodiment of the present invention, it is preferred that three or less in C(R¹) (R²) (R³) (R⁴) are a phosphonic acid group or a salt group thereof, or an alkyl group substituted with a phosphonic acid group or a salt group thereof. According to the embodiment, two or more kinds of objects to be polished can be polished at a similar speed (preferably at the same speed) and at a higher speed. In an embodiment of the present invention, it is preferred that one or more in C(R¹) (R²) (R³) (R⁴) have a hydroxyl group. In an embodiment of the present invention, it is preferred that two or less in C(R¹) (R²) (R³) (R⁴) have a hydroxyl group. According to the embodiment, two or more kinds of objects to be polished can be polished at a similar speed (preferably at the same speed) and at a higher speed. In an embodiment of the present invention, it is preferred that one or more in C(R¹) (R²) (R³) (R⁴) are a substituted or unsubstituted linear or branched alkyl group having 1 to 5 carbon atoms. According to the embodiment, two or more kinds of objects to be polished can be polished at a similar speed (preferably at the same speed) and at a higher speed. In an embodiment of the present invention, it is preferred that two or less in C(R¹) (R²) (R³) (R⁴) are a substituted or unsubstituted linear or branched alkyl group having 1 to 5 carbon atoms. According to the embodiment, two or more kinds of objects to be polished can be polished at a similar speed (preferably at the same speed) and at a higher speed.

In an embodiment of the present invention, in the above Formula (1), it is more preferred that four or more of R¹ to R⁵ are a phosphonic acid group or a salt group thereof, or an alkyl group substituted with a phosphonic acid group or a salt group thereof. According to the embodiment, two or more kinds of objects to be polished can be polished at a similar speed (preferably at the same speed) and at a higher speed. In an embodiment of the present invention, it is preferred that all of R¹ to R⁴ are a phosphonic acid group or a salt group thereof, or an alkyl group substituted with a phosphonic acid group or a salt group thereof, and it is particularly preferred that all of R¹ to R⁴ and n R⁵'s are a phosphonic acid group or a salt group thereof, or an alkyl group substituted with a phosphonic acid group or a salt group thereof. According to the embodiment, two or more kinds of objects to be polished can be polished at a similar speed (preferably at the same speed) and at a higher speed.

In an embodiment of the present invention, examples of the salt include alkali metal salt such as a sodium salt and a potassium salt, salt of element belong to the Group 2 such as a calcium salt and a magnesium salt, amine salts, ammonium salts, and the like.

In an embodiment of the present invention, the content of the organic compound in the polishing composition is preferably 0.001% by mass or more, more preferably 0.01% by mass or more, and still more preferably 0.1% by mass or more. According to the embodiment, two or more kinds of objects to be polished can be polished at a similar speed (preferably at the same speed) and at a higher speed.

In an embodiment of the present invention, the content of the organic compound in the polishing composition is preferably 5% by mass or less, more preferably 2% by mass or less, and still more preferably 1% by mass or less. According to the embodiment, two or more kinds of objects to be polished can be polished at a similar speed (preferably at the same speed) and at a higher speed.

The content of the organic compound in the polishing composition may be appropriately adjusted and set so that the polishing composition has the lower limit, the upper limit, or the range of pH to be desired as described later.

### [Water-Soluble Polymer]

In an embodiment of the present invention, the polishing composition further includes s a water-soluble polymer. According to the embodiment, three or more kinds of objects to be polished (for example, silicon oxide (SiO₂), silicon nitride (SiN), and polysilicon) can be polished at a comparable speed (preferably at the same speed) and at a high speed.

In an embodiment of the present invention, the water-soluble polymer has a plurality of hydroxyl groups. Examples of the water-soluble polymer include polymers having structural units derived from vinyl alcohol, cellulose derivatives, starch derivatives, and the like. Among these, it is preferred to include a polymer having a structural unit derived from vinyl alcohol. According to the embodiment, three or more kinds of objects to be polished (for example, silicon oxide (SiO₂), silicon nitride (SiN), and polysilicon) can be polished at a comparable speed (preferably at the same speed) and at a high speed.

In an embodiment of the present invention, the “polymer having a structural unit derived from vinyl alcohol” refers to a polymer having a vinyl alcohol unit (a structural portion represented by —CH₂—CH(OH)—; hereinafter, also referred to as “VA unit”) in one molecule. In an embodiment of the present invention, the polymer having a structural unit derived from vinyl alcohol may be a copolymer containing a non-vinyl alcohol unit (a structural unit derived from a monomer other than vinyl alcohol, hereinafter, also referred to as “non-VA unit”) in addition to the VA unit. Examples of the non-VA unit are not particularly limited, and include structural units derived from ethylene and the like. When the polymer having a structural unit derived from vinyl alcohol contains a non-VA unit, it may contain only one kind of non-VA unit, or may contain two or more kinds of non-VA units.

In an embodiment of the present invention, the content ratio (molar ratio) of the VA unit and the non-VA unit is not particularly limited, and for example, VA unit:non-VA unit (molar ratio) is preferably 1:99 to 99:1, more preferably 95:5 to 60:40, still more preferably 97:3 to 80:30, and even more preferably 98:2 to 85:15.

In an embodiment of the present invention, examples of the polymer containing a structural unit derived from vinyl alcohol include polyvinyl alcohol (PVA), vinyl alcohol/ethylene copolymer, and the like.

In an embodiment of the present invention, the saponification degree of polyvinyl alcohol is preferably 60% or more, more preferably 70% or more, still more preferably 80% or more, and even more preferably 90% or more. According to the embodiment, three or more kinds of objects to be polished can be polished at a similar speed (preferably at the same speed) and at a higher speed. In an embodiment of the present invention, the degree of saponification of polyvinyl alcohol is preferably 99% or less. According to the embodiment, three or more kinds of objects to be polished can be polished at a similar speed (preferably at the same speed) and at a higher speed.

In an embodiment of the present invention, the water-soluble polymer is a copolymer of sulfonic acid and carboxylic acid (also referred to as a “sulfonic acid/carboxylic acid copolymer”). The copolymer of sulfonic acid and carboxylic acid contains a structural unit derived from a monomer having a sulfonic acid group and a structural unit derived from a monomer having a carboxylic acid group.

In an embodiment of the present invention, examples of the monomer having a sulfonic acid group include polyalkylene glycol-based monomers (A) described in paragraphs [0019] to [0036] of JP 2015-168770 A, sulfonic acid group-containing monomers (C) described in paragraphs [0041] to [0054] of the same publication, and the like.

In an embodiment of the present invention, examples of the monomer having a carboxylic acid group include, acrylic acid, methacrylic acid, crotonic acid, α-hydroxyacrylic acid, α-hydroxymethylacrylic acid, and salts such as metal salts, ammonium salts, and organic amine salts thereof.

In an embodiment of the present invention, the molar ratio of the structural unit derived from a monomer having a sulfonic acid group and the structural unit derived from a monomer having a carboxylic acid group in the sulfonic acid/carboxylic acid copolymer is preferably 10:90 to 90:10, more preferably 30:70 to 90:10, and still more preferably 50:50 to 90:10, as the structural unit derived from a monomer having a sulfonic acid group to the structural unit derived from a monomer having a carboxylic acid group.

In an embodiment of the present invention, the weight average molecular weight of the water-soluble polymer is, in an order of preference, 1,000 or more, 3,000 or more, 6,000 or more, or 8,000 or more, from the viewpoint of hydrophilization when the object to be polished is a hydrophobic film. In an embodiment of the present invention, the weight average molecular weight of the water-soluble polymer is, in an order of preference, 150,000 or less, 100,000 or less, 80,000 or less, 40,000 or less, 20,000 or less, or 15,000 or less, from the viewpoint of slurry dispersibility. According to the embodiment, three or more kinds of objects to be polished can be polished at a similar speed (preferably at the same speed) and at a higher speed. In an embodiment of the present invention, a weight average molecular weight of the water-soluble polymer is 3,000 to 80,000. According to the embodiment, three or more kinds of objects to be polished can be polished at a similar speed (preferably at the same speed) and at a higher speed. In the present specification, the weight average molecular weight is measured by gel permeation chromatography (GPC) using polystyrene having a known molecular weight as a reference material.

In an embodiment of the present invention, the content of the water-soluble polymer is, in an order of preference, 0.001% by mass or more, 0.01% by mass or more, 0.05% by mass or more, 0.1% by mass or more, 0.2% by mass or more, 0.3% by mass or more, or 0.4% by mass or more, with respect to the total mass of the polishing composition. According to the embodiment, when the object to be polished is a hydrophobic film, there is a technical effect of improving the polishing speed by hydrophilization. In an embodiment of the present invention, the content of the water-soluble polymer is, in an order of preference, 10% by mass or less, 5% by mass or less, 3% by mass or less, 1% by mass or less, 0.9% by mass or less, 0.8% by mass or less, 0.7% by mass or less, or 0.6% by mass or less, with respect to the total mass of the polishing composition, from the viewpoint of improving slurry dispersibility and the polishing speed. According to the embodiment, three or more kinds of objects to be polished can be polished at a similar speed (preferably at the same speed) and at a higher speed.

In an embodiment of the present invention, the water-soluble polymer may be a homopolymer or a copolymer. When the water-soluble polymer is a copolymer, its form may be any of a block copolymer, a random copolymer, a graft copolymer, and an alternating copolymer.

In an embodiment of the present invention, the water-soluble polymer is at least one of polyvinyl alcohol and a copolymer of acrylic acid and sulfonic acid. According to the embodiment, three or more kinds of objects to be polished can be polished at a similar speed (preferably at the same speed) and at a higher speed.

### [Liquid Carrier]

According to an embodiment of the present invention, an organic solvent and water (particularly pure water) can be considered as a liquid carrier, but water which does not contain impurities as much as possible is preferred, from the viewpoint of contamination of the object to be polished and inhibition of the action of other components. Specifically, pure water or ultrapure water from which foreign matters have been removed through a filter after removing impurity ions by an ion exchange resin, or distilled water is preferred.

### [pH of Polishing Composition]

According to an embodiment of the present invention, the pH of the polishing composition may be acidic at pH less than 7.0, neutral at pH 7.0, or basic at pH more than 7.0, but preferably, is less than 7.0. According to the embodiment, two or more kinds of objects to be polished can be polished at a similar speed (preferably at the same speed) and at a higher speed. According to an embodiment of the present invention, the pH of the polishing composition is less than 6.0. According to an embodiment of the present invention, the pH of the polishing composition is less than 5.0. According to an embodiment of the present invention, the pH of the polishing composition is less than 4.0. According to an embodiment of the present invention, the pH of the polishing composition is 3.9 or less. According to an embodiment of the present invention, the pH of the polishing composition is 3.8 or less. According to an embodiment of the present invention, the pH of the polishing composition is 3.7 or less. According to an embodiment of the present invention, the pH of the polishing composition is 3.6 or less. According to an embodiment of the present invention, the pH of the polishing composition is 3.5 or less. According to an embodiment of the present invention, the pH of the polishing composition is 3.4 or less. According to an embodiment of the present invention, the pH of the polishing composition is 3.3 or less. According to an embodiment of the present invention, the pH of the polishing composition is 3.2 or less. According to an embodiment of the present invention, the pH of the polishing composition is 3.1 or less. According to an embodiment of the present invention, the pH of the polishing composition is 3.0 or less. According to an embodiment of the present invention, the pH of the polishing composition is less than 3.0. According to the embodiment, two or more kinds of objects to be polished can be polished at a similar speed (preferably at the same speed) and at a higher speed. According to an embodiment of the present invention, the pH of the polishing composition is 1.0 or more. According to an embodiment of the present invention, the pH of the polishing composition is 1.2 or more. According to an embodiment of the present invention, the pH of the polishing composition is more than 1.3. According to an embodiment of the present invention, the pH of the polishing composition is 1.4 or more. According to an embodiment of the present invention, the pH of the polishing composition is 1.6 or more. According to an embodiment of the present invention, the pH of the polishing composition is 1.8 or more. According to an embodiment of the present invention, the pH of the polishing composition is 2.0 or more. According to an embodiment of the present invention, the pH of the polishing composition is more than 2.0. According to an embodiment of the present invention, the pH of the polishing composition is 2.1 or more. According to an embodiment of the present invention, the pH of the polishing composition is 2.2 or more. According to an embodiment of the present invention, the pH of the polishing composition is more than 2.2. According to an embodiment of the present invention, the pH of the polishing composition is 2.3 or more. According to an embodiment of the present invention, the pH of the polishing composition is 2.4 or more. According to an embodiment of the present invention, the pH of the polishing composition is 2.5 or more. According to an embodiment of the present invention, the pH of the polishing composition is 2.6 or more. According to an embodiment of the present invention, the pH of the polishing composition is 2.8 or more. According to the embodiment, two or more kinds of objects to be polished can be polished at a similar speed (preferably at the same speed) and at a higher speed.

According to an embodiment of the present invention, the pH of the polishing composition is 2 to 6. According to the embodiment, two or more kinds of objects to be polished can be polished at a similar speed (preferably at the same speed) and at a higher speed. According to an embodiment of the present invention, the pH of the polishing composition is more than 2.0 and less than 4.0. According to the embodiment, two or more kinds of objects to be polished can be polished at a similar speed (preferably at the same speed) and at a higher speed. Further, when the pH of the polishing composition is less than 2.0, the desired effect of the present invention may not be efficiently achieved. According to an embodiment of the present invention, the pH of the polishing composition is more than 2.0 and equal to or less than 3.9, 2.1 to 3.7, 2.2 to 3.5, 2.3 to 3.3, or 2.4 to 3.1. According to the embodiment, two or more kinds of objects to be polished can be polished at a similar speed (preferably at the same speed) and at a higher speed.

According to an embodiment of the present invention, the polishing composition includes a pH adjusting agent. According to an embodiment of the present invention, the pH adjusting agent may be either acid or alkali, and may be either an inorganic compound or an organic compound. Specific examples of the acid include inorganic acids such as nitric acid, boric acid, carbonic acid, hypophosphorous acid, phosphorous acid, and phosphoric acid; organic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, and carboxylic acid, for example, citric acid, lactic acid, and the like; organic acids such as organic phosphorus-based acids such as phytic acid and hydroxyethylidene diphosphonic acid; and the like. However, one feature of the present invention is that an organic compound having a phosphonic acid group or a salt group thereof is included in the polishing composition. Therefore, according to an embodiment of the present invention, the acid as the pH adjusting agent is only an organic compound having a phosphonic acid group or a salt group thereof. Specific examples of the alkali include alkali metal hydroxides such as potassium hydroxide, amines such as ammonia, ethylenediamine, and piperazine, and quaternary ammonium salts such as tetramethylammonium and tetraethylammonium. According to an embodiment of the present invention, the polishing composition is substantially free of a pH adjusting agent other than the organic compound having a phosphonic acid group or a salt group thereof.

### [Other Components]

According to an embodiment of the present invention, the polishing composition may further include other components such as an oxidizing agent, a metal anticorrosive, an antiseptic agent, an antifungal agent, and an organic solvent for dissolving a hardly soluble organic substance.

According to an embodiment of the present invention, examples of the oxidizing agent include hydrogen peroxide, sodium peroxide, barium peroxide, ozone water, silver (II) salt, iron (III) salt, permanganic acid, chromic acid, dichromic acid, peroxodisulfuric acid, peroxophosphoric acid, peroxosulfuric acid, peroxoboric acid, performic acid, peracetic acid, perbenzoic acid, perphthalic acid, hypochlorous acid, hypobromous acid, hypoiodic acid, chloric acid, chlorous acid, perchloric acid, bromic acid, iodic acid, periodic acid, persulfuric acid, dichloroisocyanuric acid, and the like.

According to an embodiment of the present invention, the polishing composition is substantially free of an oxidizing agent. According to an embodiment of the present invention, the polishing composition is substantially free of an oxidizing agent which is hydrogen peroxide, sodium peroxide, barium peroxide, ozone water, silver (II) salt, iron (III) salt, permanganic acid, chromic acid, dichromic acid, peroxodisulfuric acid, peroxophosphoric acid, peroxosulfuric acid, peroxoboric acid, performic acid, peracetic acid, perbenzoic acid, perphthalic acid, hypochlorous acid, hypobromous acid, hypoiodic acid, chloric acid, chlorous acid, perchloric acid, bromic acid, iodic acid, periodic acid, persulfuric acid, or dichloroisocyanuric acid. According to an embodiment of the present invention, the polishing composition is substantially free of bis[(1-benzotriazolyl)methyl] phosphonic acid.

In the present specification, “substantially free” includes the case in which 0.0001 g/L or less is contained in the polishing composition, in addition to the concept of being not contained in the polishing composition at all.

According to an embodiment of the present invention, the polishing speed of silicon oxide/the polishing speed of silicon nitride is designed to be equal to or more than 0.6 and less than 2.0, equal to or more than 0.7 and less than 2.0, 0.8 to 1.5, 0.82 to 1.3, 0.90 to 1.2, or 0.92 to 1.1. When the polishing composition of the embodiment of the present invention is applied, such a polishing speed ratio can be achieved. In the embodiment of the present invention, the composition of the polishing composition may be further adjusted so as to achieve such a polishing speed ratio.

According to an embodiment of the present invention, the polishing speed of polysilicon/(the polishing speed of silicon nitride or the polishing speed of silicon oxide) is designed to be equal to or more than 0.6 and less than 2.0, 0.8 to 1.5, 0.82 to 1.3, 0.90 to 1.2, or 0.92 to 1.1. When the polishing composition of the embodiment of the present invention is applied, such a polishing speed ratio can be achieved. In the embodiment of the present invention, the composition of the polishing composition may be further adjusted so as to achieve such a polishing speed ratio.

According to an embodiment of the present invention, a value obtained by dividing a maximum value by a minimum value among the polishing speed of silicon nitride, the polishing speed of silicon oxide, and the polishing speed of polysilicon is designed to be equal to or more than 1 and less than 2.0, 1 to 1.5, 1 to 1.3, 1 to 1.2, or 1 to 1.15. When the polishing composition of the embodiment of the present invention is applied, such a polishing speed ratio can be achieved. In the embodiment of the present invention, the composition of the polishing composition may be further adjusted so as to achieve such a polishing speed ratio.

According to an embodiment of the present invention, a value obtained by dividing a maximum value by an intermediate value among the polishing speed of silicon nitride, the polishing speed of silicon oxide, and the polishing speed of polysilicon is designed to be equal to or more than 1 and less than 2.0, 1 to 1.3, 1 to 1.2, or 1 to 1.1. When the polishing composition of the embodiment of the present invention is applied, such a polishing speed ratio can be achieved. In the embodiment of the present invention, the composition of the polishing composition may be further adjusted so as to achieve such a polishing speed ratio.

According to an embodiment of the present invention, a value obtained by dividing an intermediate value by a minimum value among the polishing speed of silicon nitride, the polishing speed of silicon oxide, and the polishing speed of polysilicon is designed to be equal to or more than 1 and less than 2.0, 1 to 1.3, 1 to 1.2, or 1 to 1.1. When the polishing composition of the embodiment of the present invention is applied, such a polishing speed ratio can be achieved. In the embodiment of the present invention, the composition of the polishing composition may be further adjusted so as to achieve such a polishing speed ratio.

### [Method of Producing Polishing Composition]

According to an embodiment of the present invention, the method of producing a polishing composition is not particularly limited, and for example, the polishing composition can be obtained by stirring and mixing the above-mentioned specific abrasive grains and an organic compound having a phosphonic acid group or a salt group thereof with a liquid carrier. The temperature at which each component is mixed is not particularly limited, but is preferably 10 to 40° C., and heating may be performed for increasing a rate of dissolution. Further, the mixing time is not particularly limited.

### [Polishing Method]

According to an embodiment of the present invention, the polishing composition is appropriately used for polishing silicon nitride and silicon oxide, or silicon nitride, silicon oxide, and polysilicon. Therefore, according to an embodiment of the present invention, the polishing method is a polishing method including using the above-described polishing composition or using the polishing composition obtained by the above-described production method to polish an object to be polished including silicon nitride and silicon oxide or silicon nitride, silicon oxide, and polysilicon.

As a polishing apparatus, a general polishing apparatus having a platen to which a polishing pad (polishing cloth) is attachable, in which a holder for holding a substrate having the object to be polished and the like, a motor of which the rotational speed can be changed, and the like are mounted, can be used.

As the polishing pad, a general nonwoven fabric, polyurethane, porous fluororesin, and the like can be used without particular limitation. It is preferred that the polishing pad is subjected to grooving so that the polishing composition is collected.

The polishing conditions are not particularly limited, but for example, the rotation speed of the platen is preferably 10 to 500 rpm, the carrier rotation speed is preferably 10 to 500 rpm, and the pressure applied to the substrate having the object to be polished (polishing pressure) is preferably 0.1 to 10 psi. A method of supplying the polishing composition to the polishing pad is not particularly limited, but for example, a method of continuously supplying the polishing composition with a pump or the like is adopted. Though the amount to be supplied is not limited, it is preferred that the surface of the polishing pad is always covered with the polishing composition of the present invention.

### [Method of Producing Semiconductor Substrate]

According to an embodiment of the present invention, there is also provided a method of producing a semiconductor substrate including the above polishing method. According to the embodiment, production efficiency of the semiconductor substrate is improved.

While embodiments of the present invention have been described in detail, it is clear that the embodiments are illustrative, exemplary and not restrictive, and that the scope of the invention should be construed by the appended claims.

1. A polishing composition used for polishing an object to be polished, including abrasive grains, an organic compound, and a liquid carrier, in which the number of silanol groups per unit surface area of the abrasive grains is more than 0/nm² and equal to or less than 2.5/nm², and the organic compound has a phosphonic acid group or a salt group thereof.

2. The polishing composition according to 1., in which a surface of the abrasive grains is cationically modified.

3. The polishing composition according to 1. or 2., in which the organic compound has an unsubstituted alkyl group having 1 to 5 carbon atoms.

4. The polishing composition according to any one of 1. to 3., in which the organic compound is a compound represented by N(R¹) (R²) (R³) or a salt thereof, a compound represented by C(R¹) (R²) (R³) (R⁴) or a salt thereof, or a compound represented by the following Formula (1) or a salt thereof:

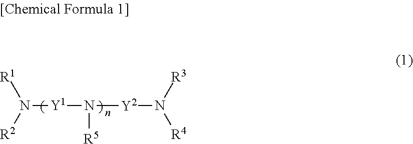

wherein Y¹ and Y² each independently represent a linear or branched alkylene group having 1 to 5 carbon atoms, n is an integer of 0 to 4, and R¹ to R⁵ each independently represent a hydrogen atom, a phosphonic acid group or a salt group thereof, a hydroxyl group, or a substituted or unsubstituted linear or branched alkyl group having 1 to 5 carbon atoms, in which one or more of R¹ to R⁵ are a phosphonic acid group or a salt group thereof or an alkyl group substituted with a phosphonic acid group or a salt group thereof.

5. The polishing composition according to any one of 1. to 4., in which the organic compound has two or more phosphonic acid groups or salt groups thereof or two or more alkyl groups substituted with a phosphonic acid group or a salt group thereof.

6. The polishing composition according to any one of 1. to 5., in which the abrasive grains are silica.

7. The polishing composition according to any one of 1. to 6., further including a water-soluble polymer.

8. The polishing composition according to 7., in which a weight average molecular weight of the water-soluble polymer is 3,000 to 80,000.

9. The polishing composition according to 7. or 8., in which the water-soluble polymer is at least one of polyvinyl alcohol and a copolymer of acrylic acid and sulfonic acid.

10. The polishing composition according to any one of 1. to 9., in which the pH is less than 7.0.

11. The polishing composition according to any one of 1. to 10., in which the object to be polished includes silicon nitride and silicon oxide.

12. The polishing composition according to 11., in which a polishing speed of silicon oxide/a polishing speed of silicon nitride is designed to be equal to or more than 0.7 and less than 2.0.

13. The polishing composition according to 11. or 12., in which the object to be polished further includes polysilicon.

14. The polishing composition according to 13., in which the polishing speed of polysilicon/(the polishing speed of silicon nitride or the polishing speed of silicon oxide) is designed to be equal to or more than 0.6 and less than 2.0.

15. The polishing composition according to 13. or 14., in which a value obtained by dividing a maximum value by a minimum value among the polishing speed of silicon nitride, the polishing speed of silicon oxide, and the polishing speed of polysilicon is designed to be equal to or more than 1 and less than 2.0.

16. The polishing composition according to any one of 13. to 15., in which a value obtained by dividing a maximum value by an intermediate value among the polishing speed of silicon nitride, the polishing speed of silicon oxide, and the polishing speed of polysilicon is designed to be equal to or more than 1 and less than 2.0, and a value obtained by dividing the intermediate value by a minimum value thereof is designed to be equal to or more than 1 and less than 2.0.

### EXAMPLES

The present invention will be described in more detail, by means of the following examples and comparative examples. However, the technical scope of the present invention is not limited to the following examples. In addition, unless otherwise stated, “%” and “parts” mean “% by mass” and “parts by mass”, respectively. Further, in the following examples, unless otherwise stated, the operation was performed under conditions of room temperature (25° C.)/relative humidity of 40 to 50% RH.

### Example 1

### (Preparation of Polishing Composition)

Abrasive grains A were added in an amount of 0.5% by mass to pure water as a liquid carrier, with respect to 100% by mass of the final polishing composition, 1-hydroxyethane-1,1-diphosphonic acid was added in an amount such that the pH of the final polishing composition is 2.5, and polyvinyl alcohol as a water-soluble polymer (molecular weight of about 10,000: polymerization degree of 220, saponification degree of 99% or more) was added in an amount of 0.50% by mass with respect to the final polishing composition, thereby preparing the polishing composition of Example 1.

### <Calculation Method of Number of Silanol Groups>

The number of silanol groups per unit surface area of the abrasive grains (unit: /nm²) was calculated by the following method, after each parameter was measured or calculated by the following measurement method or calculation method.

More specifically, C in the following equation is the total mass of the abrasive grains, and S in the following equation is the BET specific surface area of the abrasive grains. More specifically, first, 1.50 g as a solid content of abrasive grains was collected in a 200 ml beaker, 100 ml of pure water was added to form a slurry, and then 30 g of sodium chloride was added and dissolved. Next, 1N hydrochloric acid was added to adjust the pH of the slurry to about 3.0 to 3.5, and then pure water was added so that the slurry was 150 ml. For this slurry, an automatic titrator (Hiranuma Inc., COM-1700) was used to adjust the pH to 4.0 with 0.1 N sodium hydroxide at 25° C., and the volume V [L] of the 0.1 N sodium hydroxide solution required to raise the pH from 4.0 to 9.0 was measured by pH titration. The average silanol group density (the number of silanol groups) can be calculated by the following equation.

ρ=(c×V×N_{A}×10⁻²¹)/(C×S) [Equation 1]

wherein

ρ represents an average silanol group density (the number of silanol groups) (/nm²);

c represents a concentration (mol/L) of the sodium hydroxide solution used for the titration;

V represents a volume (L) of sodium hydroxide solution required to raise the pH from 4.0 to 9.0;

N_{A} represents the Avogadro constant (/mol);

C represents a total mass (solid content) (g) of the abrasive grains; and

S represents the weighted average value (nm²/g) of a BET specific surface area of the abrasive grains.

### <Calculation Method of Particle Size>

The average primary particle size of the abrasive grains was calculated from a specific surface area of the abrasive grains by the BET method measured using “Flow Sorb II 2300” manufactured by Micromeritics, and a density of the abrasive grains. The average secondary particle size of the abrasive grains was measured by a dynamic light scattering particle size/particle size distribution apparatus, UPA-UTI151 manufactured by Nikkiso Co., Ltd.

<Measurement Method of pH>

The pH of the polishing composition (liquid temperature: 25° C.) was confirmed by a pH meter (manufactured by Horiba, Ltd., model number: LAQUA).

### Examples 2 to 8 and Comparative Examples 1 to 3

### (Preparation of Polishing Composition)

Each polishing composition was prepared in the same manner as in Example 1 except that the type and content of each component and the pH of the polishing composition were changed as shown in the following Table 1.

Each polishing composition prepared above was evaluated for a polishing speed (removal rate) (Å/min) according to the following method. The results are also shown in the following Table 1.

### <Polishing Test>

Each polishing composition was used to polish the surface of the object to be polished under the following conditions. As the objects to be polished, silicon nitride having a film thickness of 2,500 Å, TEOS (silicon oxide) having a film thickness of 10,000 Å, and polysilicon having a film thickness of 4,500 Å, formed on the surface of a silicon substrate, were used, respectively.

### [Polishing Apparatus and Polishing Conditions]

Polishing apparatus: a tabletop polishing machine (EJ-380IN manufactured by ENGIS JAPAN Corporation)

Polishing pad: IC1000 (manufactured by The Dow Chemical Company)

Polishing pressure: 3 psi

Rotation speed of platen: 60 rpm

Rotation speed of carrier: 60 rpm

Supply amount of polishing composition: 50 mL/min

Polishing time: 60 sec

In-situ dressing

Work size: 30 mm square.

### [Evaluation]

For each polishing composition, the following items were measured and evaluated.

### [Measurement of Polishing Speed (Removal Rate)]

The polishing speed (Å/min) was calculated by the following Formula (1).

$$\begin{matrix}[ Equation 2 ] & \\ Polishing speed ( Å / min ) = \frac{\begin{matrix}[ Film thickness of object to be polished before polishing ( Å ) ] - \\ [ Film thickness of object to be polished after polishing ( Å ) ]\end{matrix}}{[ Polishing time ( min ) ]} & Formula ( 1 )\end{matrix}$$

Each film thickness was obtained by a light interference type film thickness measurement apparatus, and evaluation was made by dividing the difference of a film thickness before and after polishing by a polishing time. The evaluation results are also shown in Table 1.

TABLE 1

| | | | | | Organic | | Water-soluble polymer | | | | | |
|---|---|---|---|---|---|---|---|---|---|---|---|---|
| | Abrasive Grains | | | | compound | | | | Weight | | | |
| | | Silanol | Surface | | (or additive) | | | | average | Polishing speed | | |
| | | group | modifi- | Concentration | Acid | | | Concentration | molecular | [Å/min] | | |
| | Type | density | cation | (% by mass) | species | pH | | (% by mass) | weight | TEOS | SiN | Poly Si |
| Example 1 | Abrasive grains A | 1.8 | — | 0.50 | HEDP | 2.5 | PVA | 0.50 | About 10000 | 233 | 243 | 233 |
| Example 2 | Abrasive grains A | 1.8 | — | 0.50 | NTMP | 2.5 | PVA | 0.50 | About 10000 | 227 | 223 | 243 |
| Example 3 | Abrasive grains A | 1.8 | — | 0.50 | EDTMP | 2.5 | PVA | 0.50 | About 10000 | 205 | 209 | 222 |
| Example 4 | Abrasive grains A | 1.8 | — | 0.50 | DTPMP | 2.5 | PVA | 0.50 | About 10000 | 225 | 229 | 232 |
| Example 5 | Abrasive grains B | 1.8 | APTES | 0.50 | HEDP | 2.5 | PVA | 0.50 | About 10000 | 294 | 273 | 271 |
| Example 6 | Abrasive grains A | 1.8 | — | 1.50 | EDTMP | 2 | PVA | 0.50 | About 10000 | 383 | 354 | 395 |
| Example 7 | Abrasive grains C | 2.4 | — | 1.50 | EDTMP | 2 | PVA | 0.50 | About 10000 | 315 | 302 | 302 |
| Example 8 | Abrasive grains A | 1.8 | — | 0.50 | HEDP | 2.5 | PVA | 0.50 | About 75000 | 175 | 184 | 167 |
| Comparative | Abrasive grains D | 5.7 | — | 0.50 | HEDP | 2.5 | PVA | 0.50 | About 10000 | 89 | 143 | 176 |
| Example 1 | | | | | | | | | | | | |
| Comparative | Abrasive grains E | 5.7 | APTES | 0.50 | HEDP | 2.5 | PVA | 0.50 | About 10000 | 68 | 124 | 135 |
| Example 2 | | | | | | | | | | | | |
| Comparative | Abrasive grains A | 1.8 | — | 0.50 | Maleic | 2.5 | PVA | 0.50 | About 10000 | 162 | 23 | 124 |
| Example 3 | | | | | acid | | | | | | | |

Abrasive grains A: Unmodified colloidal silica (average primary particle size: 35 nm, average secondary particle size: 70 nm, average degree of association: 2.0)
Abrasive grains B: Cationic modified colloidal silica having an amino group immobilized on the surface by reaction of aminopropyltriethoxysilane (APTES) (average primary particle size: 35 nm, average secondary particle size: 70 nm, average degree of association: 2.0)
Abrasive grains C: Unmodified colloidal silica (average primary particle size: 52 nm, average secondary particle size: 118 nm, average degree of association: 2.3)
Abrasive grains D: Unmodified colloidal silica (average primary particle size: 35 nm, average secondary particle size: 70 nm, average degree of association: 2.0)
Abrasive grains E: Cationic modified colloidal silica having an amino group immobilized on the surface by reaction of aminopropyltriethoxysilane (APTES) with colloidal silica (average primary particle size: 35 nm, average secondary particle size: 70 nm, average degree of association: 2.0)
HEDP: 1-hydroxyethane-1,1-diphosphonic acid (etidronic acid)
NTMP: Nitrilotris (methylenephosphonic acid)
EDTMP: ethylenediamine tetra(methylene phosphonic acid) 4 Na
DTPMP: diethylenetriamine penta(methylene phosphonic acid)

### <Discussion>

According to the polishing composition of the examples, all of the polishing speeds of two or three kinds of objects to be polished under the same condition were 150 Å/min or more, and the polishing speed of silicon oxide/polishing speed of silicon nitride under the same condition was equal to or more than 0.7 and less than 2.0, and thus, the desired effect of the present invention is achieved. However, in the polishing composition of the comparative examples, one or more of the polishing speeds of two or three kinds of objects to be polished under the same condition were less than 150 Å/min, the polishing speed of silicon oxide/the polishing speed of silicon nitride under the same condition was less than 0.7 or equal to or more than 2.0, and the desired effect of the present invention was not achieved.

The present application is based on the Japanese patent application No. 2019-066859 filed on Mar. 29, 2019, and a disclosed content thereof is entirely incorporated herein by reference.

What is claimed is:

1. A polishing composition used for polishing an object to be polished, the polishing composition comprising:
abrasive grains; an organic compound; and a liquid carrier,
wherein the number of silanol groups per unit surface area of the abrasive grains is more than 0/nm² and equal to or less than 2.5/nm², and
the organic compound has a phosphonic acid group or a salt group thereof.

2. The polishing composition according to claim 1, wherein a surface of the abrasive grains is cationically modified.

3. The polishing composition according to claim 1, wherein the organic compound has an unsubstituted alkyl group having 1 to 5 carbon atoms.

4. The polishing composition according to claim 1, wherein the organic compound is a compound represented by N(R¹) (R²) (R³) or a salt thereof, a compound represented by C(R¹) (R²) (R³) (R⁴) or a salt thereof, or a compound represented by the following Formula (1) or a salt thereof: 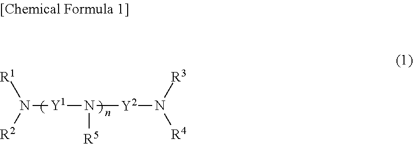
wherein Y¹ and Y² each independently represent a linear or branched alkylene group having 1 to 5 carbon atoms,
n is an integer of 0 to 4, and
R¹ to R⁵ each independently represent a hydrogen atom, a phosphonic acid group or a salt group thereof, a hydroxyl group, or a substituted or unsubstituted linear or branched alkyl group having 1 to 5 carbon atoms,
in which one or more of R¹ to R⁵ are a phosphonic acid group or a salt group thereof or an alkyl group substituted with a phosphonic acid group or a salt group thereof.

5. The polishing composition according to claim 1, wherein the organic compound has two or more phosphonic acid groups or salt groups thereof or two or more alkyl groups substituted with a phosphonic acid groups or a salt group thereof.

6. The polishing composition according to claim 1, wherein the abrasive grains are silica.

7. The polishing composition according to claim 1, further comprising a water-soluble polymer.

8. The polishing composition according to claim 7, wherein a weight average molecular weight of the water-soluble polymer is 3,000 to 80,000.

9. The polishing composition according to claim 7, wherein the water-soluble polymer is at least one of polyvinyl alcohol and a copolymer of acrylic acid and sulfonic acid.

10. The polishing composition according to claim 1, wherein a pH of the polishing composition is less than 7.0.

11. The polishing composition according to claim 1, wherein the object to be polished includes silicon nitride and silicon oxide.

12. The polishing composition according to claim 11, wherein a polishing speed of silicon oxide/a polishing speed of silicon nitride is designed to be equal to or more than 0.7 and less than 2.0.

13. The polishing composition according to claim 11, wherein the object to be polished further includes polysilicon.

14. The polishing composition according to claim 13, wherein a polishing speed of polysilicon/(the polishing speed of silicon nitride or the polishing speed of silicon oxide) is designed to be equal to or more than 0.6 and less than 2.0.

15. The polishing composition according to claim 13, wherein a value obtained by dividing a maximum value by a minimum value among the polishing speed of silicon nitride, the polishing speed of silicon oxide, and the polishing speed of polysilicon is designed to be equal to or more than 1 and less than 2.0.

16. The polishing composition according to claim 13, wherein a value obtained by dividing a maximum value by an intermediate value among the polishing speed of silicon nitride, the polishing speed of silicon oxide, and the polishing speed of polysilicon is designed to be equal to or more than 1 and less than 2.0, and a value obtained by dividing the intermediate value by a minimum value among the polishing speed of silicon nitride, the polishing speed of silicon oxide, and the polishing speed of polysilicon is designed to be equal to or more than 1 and less than 2.0.
